(19) United States
(12) Patent Application Publication
(10) Pub. No.: US 2025/0151292 A1
(43) Pub. Date: May 8, 2025

(54) MEMORY DEVICE HAVING COP STRUCTURE AND MEMORY PACKAGE INCLUDING THE SAME

(71) Applicant: Samsung Electronics Co., Ltd., Suwon-si (KR)

(72) Inventors: Changyoung Lee, Suwon-si (KR); Keonwoo Park, Suwon-si (KR); Hyunchul Yoon, Suwon-si (KR)

(21) Appl. No.: 18/732,795

(22) Filed: Jun. 4, 2024

(30) Foreign Application Priority Data
Nov. 7, 2023 (KR) 10-2023-0152288

(51) Int. Cl. H10B 80/00; G06F 11/10; G11C 11/408; G11C 11/4091; H01L 23/00; H01L 25/065; H01L 25/18

(52) U.S. Cl. CPC H10B 80/00; G06F 11/1068; G11C 11/4085; G11C 11/4087; G11C 11/4091; H01L 24/08; H01L 25/0657; H01L 25/18; H01L 2224/08145; H01L 2225/06506; H01L 2225/06513; H01L 2225/06541; H01L 2225/06562; H01L 2225/06586; H01L 2924/1431; H01L 2924/1436

(57) ABSTRACT

A memory device includes a first semiconductor layer and a second semiconductor layer. The first semiconductor layer includes a memory cell array. The memory cell array is connected to a plurality of wordlines and a plurality of bitlines, and includes a plurality of normal memory cells storing normal data and a plurality of error correction code (ECC) memory cells storing ECC data. The second semiconductor layer is disposed with respect to the first semiconductor layer in a vertical direction, and includes a peripheral circuit. The peripheral circuit controls the memory cell array, and includes a row decoder. At least a portion of a region in which the plurality of ECC memory cells are disposed in the first semiconductor layer and at least a portion of a region in which the row decoder is disposed in the second semiconductor layer overlap in a plan view.

### CROSS-REFERENCE TO RELATED APPLICATION

This application claims priority under 35 USC § 119 to Korean Patent Application No. 10-2023-0152288 filed on Nov. 7, 2023 in the Korean Intellectual Property Office (KIPO), the contents of which are herein incorporated by reference in their entirety.

### BACKGROUND

The present disclosure relates generally to semiconductor integrated circuits, and more particularly to memory devices having cell over periphery (COP) structures, and memory packages including the memory devices.

Semiconductor memory devices may be divided into two categories depending upon whether or not they retain stored data when disconnected from a power supply. These categories include volatile memory devices, which lose stored data when disconnected from power, and nonvolatile memory devices, which retain stored data when disconnected from power. While volatile memory devices may perform read and write operations at a high speed, contents stored therein may be lost at power-off. Since nonvolatile memory devices retain contents stored therein even at power-off, they may be used to store data that needs to be retained.

Various structures are being adopted to increase the integration degree of memory devices and reduce the size of memory devices. However, the reduction of the size of memory devices is limited because the memory device should still include a peripheral circuit for driving a memory cell array and a wiring structure to electrically connect the memory cell array with the peripheral circuit. Recently, methods are used in which elements included in the memory device are fabricated on separate wafers, rather than being fabricated on a single wafer, and then bonded to each other.

### SUMMARY

At least one example embodiment of the present disclosure provides a memory device that is efficiently reduced in size.

At least one example embodiment of the present disclosure provides a memory package including the memory device.

According to example embodiments, a memory device includes a first semiconductor layer and a second semiconductor layer. The first semiconductor layer includes a memory cell array. The memory cell array is connected to a plurality of wordlines and a plurality of bitlines, and includes a plurality of normal memory cells storing normal data and a plurality of error correction code (ECC) memory cells storing ECC data. The plurality of wordlines extend in a first direction. The plurality of bitlines extend in a second direction crossing the first direction. The second semiconductor layer is disposed with respect to the first semiconductor layer in a third direction perpendicular to both the first direction and the second direction, and includes a peripheral circuit. The peripheral circuit controls the memory cell array, and includes a row decoder. At least a portion of a region in which the plurality of ECC memory cells are disposed in the first semiconductor layer and at least a portion of a region in which the row decoder is disposed in the second semiconductor layer overlap in a plan view.

According to example embodiments, a memory package includes a base substrate and a plurality of memory chips stacked on the base substrate. Each of the plurality of memory chips includes a first semiconductor layer and a second semiconductor layer. The first semiconductor layer includes a memory cell array. The memory cell array is connected to a plurality of wordlines and a plurality of bitlines, and includes a plurality of normal memory cells storing normal data and a plurality of error correction code (ECC) memory cells storing ECC data. The plurality of wordlines extend in a first direction. The plurality of bitlines extend in a second direction crossing the first direction. The second semiconductor layer is disposed with respect to the first semiconductor layer in a third direction perpendicular to both the first direction and the second direction, and includes a peripheral circuit. The peripheral circuit controls the memory cell array, and includes a row decoder. At least a portion of a region in which the plurality of ECC memory cells are disposed in the first semiconductor layer and at least a portion of a region in which the row decoder is disposed in the second semiconductor layer overlap in a plan view.

According to example embodiments, a memory device includes a first semiconductor layer and a second semiconductor layer. The first semiconductor layer includes a memory cell array connected to a plurality of wordlines and a plurality of bitlines, and a first ponding pad. The plurality of wordlines extend in a first direction. The plurality of bitlines extend in a second direction crossing the first direction. The second semiconductor layer is disposed with respect to the first semiconductor layer in a third direction perpendicular to both the first direction and the second direction, and includes a peripheral circuit controlling the memory cell array, and a second bonding pad connected to the first bonding pad. The memory cell array includes a plurality of normal memory cells and a plurality of error correction code (ECC) memory cells. The plurality of normal memory cells store normal data, and include first normal memory cells and second normal memory cells that are spaced apart from each other. The plurality of ECC memory cells store ECC data, and include first ECC memory cells and second ECC memory cells that correspond to the first normal memory cells and the second normal memory cells, respectively. The peripheral circuit includes a first row decoder, first and second normal bitline sense amplifiers, first and second ECC bitline sense amplifiers, first sub-wordline drivers and first sub-wordline drivers. The first row decoder drives the first and second normal memory cells and the first and second ECC memory cells. The first and second normal bitline sense amplifiers drive the first and second normal memory cells, respectively. The first and second ECC bitline sense amplifiers drive the first and second ECC memory cells, respectively. The first sub-wordline drivers drive the first normal memory cells and the first ECC memory cells. The first sub-wordline drivers drive the second normal memory cells and the second ECC memory cells. The first and second ECC memory cells are disposed in a first region between the first and second normal memory cells in the first semiconductor layer. The first row decoder and the first and second ECC bitline sense amplifiers are disposed in a second region in the second semiconductor layer that overlaps the first region in the first semiconductor layer in a plan view. The first and second normal bitline sense amplifiers and the first and second sub-wordline drivers are disposed in a third region in the second semiconductor layer that is adjacent to the second region in the second semiconductor layer.

The memory device and the memory package according to example embodiments may have or adopt a structure in which the peripheral circuit and the memory cell array are stacked, e.g., the COP structure in which the peripheral circuit is formed below and then the memory cell array is stacked on the peripheral circuit. Accordingly, the memory device and the memory package may have a relatively small size.

In addition, in the memory device and the memory package according to example embodiments, the ECC memory cells included in the memory cell array and the row decoder included in the peripheral circuit may be arranged to vertically overlap each other. As a result, an area occupied by the ECC memory cells in the first semiconductor layer may be reduced, and/or an area occupied by the row decoder in the second semiconductor layer may be reduced. Accordingly, the memory device may be further reduced in size.

### BRIEF DESCRIPTION OF THE DRAWINGS

Illustrative, non-limiting example embodiments will be more clearly understood from the following detailed description taken in conjunction with the accompanying drawings, wherein like reference numerals (when used) indicate corresponding elements throughout the several views, and in which:

FIG. 1 is a perspective schematic view of a memory device according to example embodiments;

FIG. 2 is a schematic cross-sectional view of a memory device according to example embodiments;

FIG. 3 is a schematic block diagram illustrating an example of a memory device according to example embodiments;

FIG. 4 is a schematic diagram illustrating an example of a memory cell array included in the memory device of FIG. 3;

FIG. 5 is a schematic perspective view of the example of a memory device of FIG. 1;

FIGS. 6, 7A, 7B, 8A, 8B, 8C and 9 are schematic diagrams for describing the memory device of FIG. 5;

FIG. 10 is a schematic perspective view of the example of a memory device of FIG. 1;

FIG. 11 is a schematic diagram for describing the memory device of FIG. 10;

FIGS. 12A and 12B are schematic perspective views of a memory device according to example embodiments;

FIGS. 13A and 13B are schematic cross-sectional views of a memory package according to example embodiments; and

FIG. 14 is a schematic block diagram illustrating a memory system according to example embodiments.

### DETAILED DESCRIPTION

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

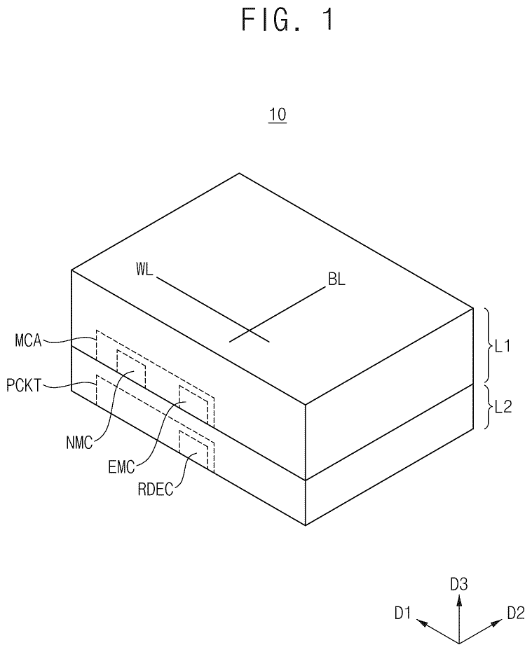

FIG. 1 is a schematic perspective view of a memory device according to example embodiments.

In FIG. 1, two directions that are each parallel or substantially parallel to a first surface (e.g., a top surface) of a substrate and crossing each other are referred to as a first direction D1 (e.g., an X-axis direction) and a second direction D2 (e.g., a Y-axis direction), respectively. In addition, a direction vertical or substantially vertical (i.e., perpendicular) to the first surface of the substrate is referred to herein as a third direction D3 (e.g., a Z-axis direction). For example, the first and second directions D1 and D2 may be perpendicular or substantially perpendicular to each other. In addition, the third direction D3 may be perpendicular or substantially perpendicular to both the first and second directions D1 and D2. Further, a direction indicated by an arrow in the figures and a reverse direction thereof are considered as the same direction. The definition of the first, second and third directions D1, D2 and D3 are same in the subsequent figures.

Referring to FIG. 1, a memory device 10 includes a first semiconductor layer L1 and a second semiconductor layer L2.

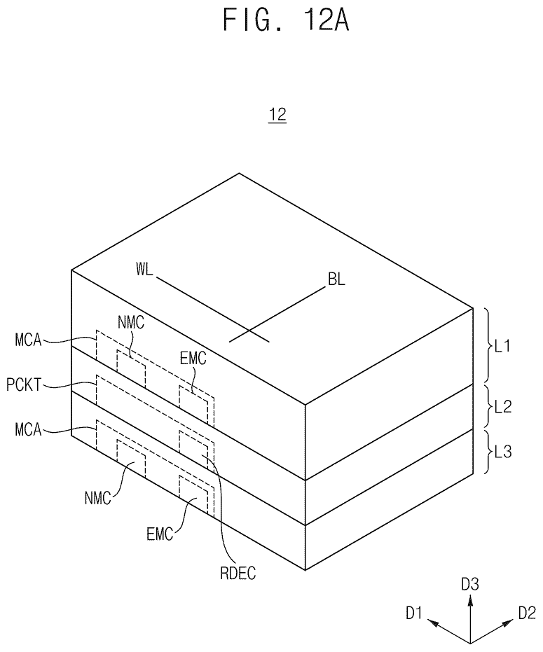

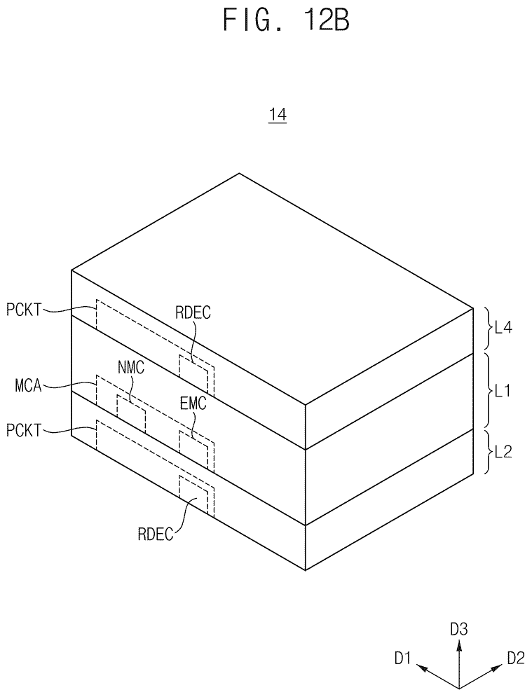

The first semiconductor layer L1 and the second semiconductor layer L2 are disposed or stacked in the third direction D3. For example, the first semiconductor layer L1 may be stacked on the second semiconductor layer L2 in the third direction D3, and the second semiconductor layer L2 may be disposed under (e.g., directly beneath or indirectly beneath) the first semiconductor layer L1 in the third direction D3. However, example embodiments are not limited thereto. For example, the memory device 10 may be turned over (i.e., vertically flipped) during the manufacturing process, and thus the second semiconductor layer L2 may be stacked on the first semiconductor layer L1 in the third direction D3. In some example embodiments, as will be described with reference to FIGS. 12A and 12B, three or more semiconductor layers may be stacked in the third direction D3.

The first semiconductor layer L1 includes a plurality of wordlines WL, a plurality of bitlines BL and a memory cell array MCA. Thus, the first semiconductor layer L1 may be referred to as a memory cell region (MCR) or a cell wafer.

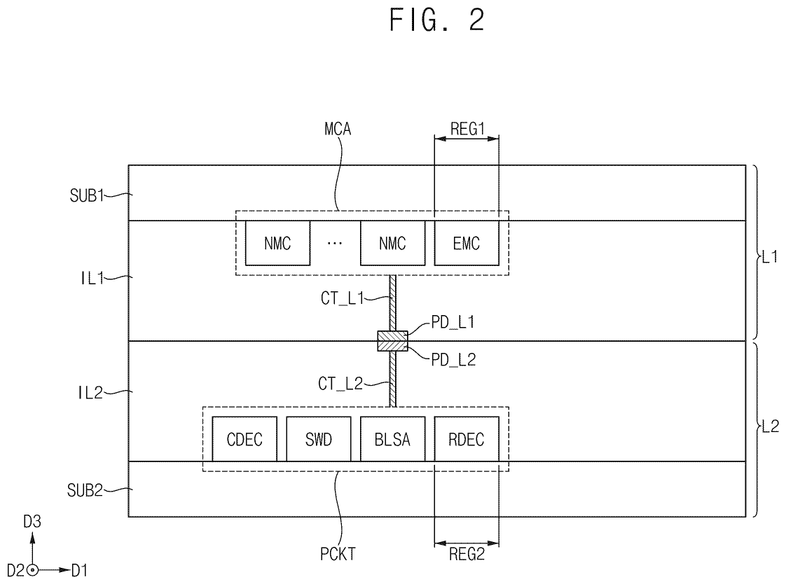

For example, as will be described with reference to FIG. 2, the first semiconductor layer L1 may include a first substrate. The plurality of wordlines WL, the plurality of bitlines BL and the memory cell array MCA may be disposed and/or formed on the first substrate. For example, each of the plurality of wordlines WL may extend in the first direction D1, and the plurality of wordlines WL may be arranged (i.e., separated from one another) along the second direction D2. For example, each of the plurality of bitlines BL may extend in the second direction D2, and the plurality of bitlines BL may be arranged (i.e., separated from one another) along the first direction D1. For example, the memory cell array MCA may be connected to the plurality of wordlines WL and the plurality of bitlines BL.

The second semiconductor layer L2 may include a peripheral circuit PCKT that controls the memory cell array MCA. Thus, the second semiconductor layer L2 may be referred to as a peripheral circuit region (PCR) or a peripheral wafer.

For example, as will be described with reference to FIG. 2, the second semiconductor layer L2 may include a second substrate. The peripheral circuit PCKT may be disposed and/or formed on the second substrate. For example, the peripheral circuit PCKT may control the memory cell array MCA.

In some example embodiments, the first semiconductor layer L1 and the second semiconductor layer L2 may be manufactured separately, and then the first semiconductor layer L1 and the second semiconductor layer L2 may be connected to each other by a bonding scheme (or method). The term “connected” (or “connecting,” or like terms, such as “contact” or “contacting”), as may be used herein, may refer to a physical and/or electrical connection between two or more elements, and may include other intervening elements. As used herein, the term “and/or” includes any and all combinations of one or more of the associated listed items. For example, as will be described with reference to FIG. 2, the first semiconductor layer L1 may include a first bonding pad, the second semiconductor layer L2 may include a second bonding pad, and the bonding scheme may represent a method of electrically or physically connecting a bonding metal pattern (e.g., the first bonding pad) formed in the first semiconductor layer L1 to a bonding metal pattern (e.g., the second bonding pad) formed in the second semiconductor layer L2. For example, the bonding pads may be formed of copper (Cu), and the bonding scheme may be a Cu—Cu bonding scheme. Alternatively, the bonding pads may be formed of aluminum (Al) or tungsten (W).

The memory cell array MCA may include a plurality of normal memory cells NMC and a plurality of error correction code (ECC) memory cells EMC. The plurality of normal memory cells NMC may store normal data (e.g., user data), and the plurality of ECC memory cells EMC may store ECC data (e.g., parity data) that is associated with or related to the normal data. The peripheral circuit PCKT may include a row decoder RDEC. The row decoder RDEC may control the plurality of normal memory cells NMC and the plurality of ECC memory cells EMC. The plurality of ECC memory cells EMC in the first semiconductor layer L1 and the row decoder RDEC in the second semiconductor layer L2 may be arranged to partially and/or completely overlap in a plan view or on a plane, which will be described with reference to FIGS. 2, 5 and 10. The term “overlap” (or “overlapping,” or like terms), as may be used herein, is may broadly refer to a first element that intersects with at least a portion of a second element in the vertical direction (e.g., the third direction D3), but does not require that the first and second elements be completely aligned with one another in a horizontal plane (e.g., in the first direction D1 and/or the second direction D2).

In computing, telecommunication, information theory, and coding theory, forward error correction (FEC) or channel coding is a technique used for controlling errors in data transmission over unreliable or noisy communication channels. For example, the sender encodes the message in a redundant way, most often by using an error correction code or error correcting code (ECC). The redundancy allows the receiver not only to detect errors that may occur anywhere in the message, but often to correct a limited number of errors. Therefore, a reverse channel to request re-transmission may not be needed.

For example, when the normal data is written into the plurality of normal memory cells NMC, the ECC data associated with the normal data to be written may be generated using an ECC encoder and an ECC. The normal data and the ECC data may be stored in the plurality of normal memory cells NMC and the plurality of ECC memory cells EMC, respectively. For example, when the normal data is read from the plurality of normal memory cells NMC, an ECC decoding may be performed on the normal data based on the ECC data using an ECC decoder and an ECC. When it is determined based on a result of the ECC decoding that the normal data includes at least one error bit, the ECC decoder may perform an error correction and output corrected normal data in a case of a correctable error (CE), and the ECC decoder may declare that the ECC decoding is impossible in a case of an uncorrectable error (UE). For example, the ECC may be a single error correction (SEC) code or a single error correction and double error detection (SECDED) code, but example embodiments are not limited thereto.

FIG. 2 is a schematic cross-sectional view of a memory device according to example embodiments.

Referring to FIGS. 1 and 2, the first semiconductor layer L1 may include a first substrate SUB1, the memory cell array MCA, a first bonding pad PD_L1, a first contact CT_L1 and a first insulating layer IL1. The second semiconductor layer L2 may include a second substrate SUB2, the peripheral circuit PCKT, a second bonding pad PD_L2, a second contact CT_L2 and a second insulating layer IL2.

The first substrate SUB1 may be a supporting layer that supports components (or elements) of the first semiconductor layer L1, and the second substrate SUB2 may be a supporting layer that supports components of the second semiconductor layer L2. For example, each of the first and second substrates SUB1 and SUB2 may be a silicon substrate, and may be referred to as a base substrate; however, the first substrate SUB1 and the second substrate SUB2 need not be formed of the same material. The first insulating layer IL1 may cover the components of the first semiconductor layer L1, and the second insulating layer IL2 may cover the components of the second semiconductor layer L2. The term “cover” (or “covering,” “covers,” or like terms), as may be used herein, may broadly refer to an element, structure or layer that is on or over another element, structure or layer, either directly or with one or more other intervening elements, structures or layers therebetween.

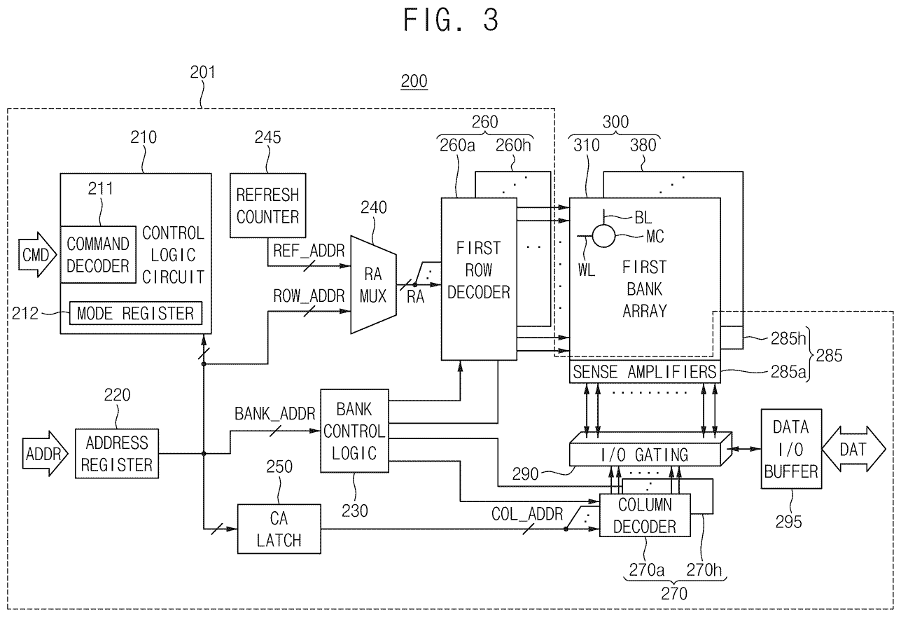

The memory cell array MCA may include the plurality of normal memory cells NMC and the plurality of ECC memory cells EMC. The peripheral circuit PCKT may include the row decoder RDEC, bitline sense amplifiers BLSA, sub-wordline drivers SWD, a column decoder CDEC, etc. As described with reference to FIG. 1, the normal memory cells NMC and the ECC memory cells EMC may store the normal data and the ECC data, respectively. The row decoder RDEC, the bitline sense amplifiers BLSA, the sub-wordline drivers SWD and the column decoder CDEC may be used to drive the normal memory cells NMC and the ECC memory cells EMC. A detailed configuration of the peripheral circuit PCKT will be described with reference to FIG. 3.

The memory cell array MCA and the peripheral circuit PCKT may be electrically connected to each other by the first and second contacts CT_L1 and CT L2 and the first and second bonding pads PD_L1 and PD_L2. For example, the memory cell array MCA may be electrically connected to the first contact CT_L1 and the first bonding pad PD_L1, the peripheral circuit PCKT may be electrically connected to the second contact CT_L2 and the second bonding pad PD_L2, and the memory cell array MCA and the peripheral circuit PCKT may be electrically connected to each other by electrically connecting the first bonding pad PD_L1 with the second bonding pad PD_L2. Although not illustrated in detail, at least one conductive line and/or contact may be further formed to connect the memory cell array MCA with the first bonding pad PD_L1, and at least one conductive line and/or contact may be further formed to connect the peripheral circuit PCKT with the second bonding pad PD_L2.

In some example embodiments, the first semiconductor layer L1 may be manufactured by forming the memory cell array MCA, the first bonding pad PD_L1, the first contact CT L1 and the first insulating layer IL1 in and/or on the first substrate SUB1, the second semiconductor layer L2 may be manufactured by forming the peripheral circuit PCKT, the second bonding pad PD_L2, the second contact CT_L2 and the second insulating layer IL2 in and/or on the second substrate SUB2, the first semiconductor layer L1 may be turned over, and the bonding pads PD_L1 and PD_L2 may be connected using the bonding scheme. As a result, the first and second semiconductor layers L1 and L2 may be electrically connected in the third direction D3.

Although FIG. 2 may illustrate an example where the semiconductor layers L1 and L2 include a pair of the bonding pads PD_L1 and PD_L2 and a pair of the contacts CT_L1 and CT_L2, example embodiments are not limited thereto, and the number of bonding pads and the number of contacts included in the semiconductor layers L1 and L2 may be variously determined according to example embodiments.

At least a portion of a region (or area) REG1 in the first semiconductor layer L1 where the plurality of ECC memory cells EMC are disposed and at least a portion of a region REG2 in the second semiconductor layer L2 where the row decoder RDEC is disposed may overlap in a plan view or on a plane. In other words, when the first and second semiconductor layers L1 and L2 are overlapped and viewed on the same plane, the region REG1 and the region REG2 may coincide, and/or a portion or all of the region REG1 may be included in the region REG2, or a portion or all of the region REG2 may be included in the region REG1, in the third direction D3.

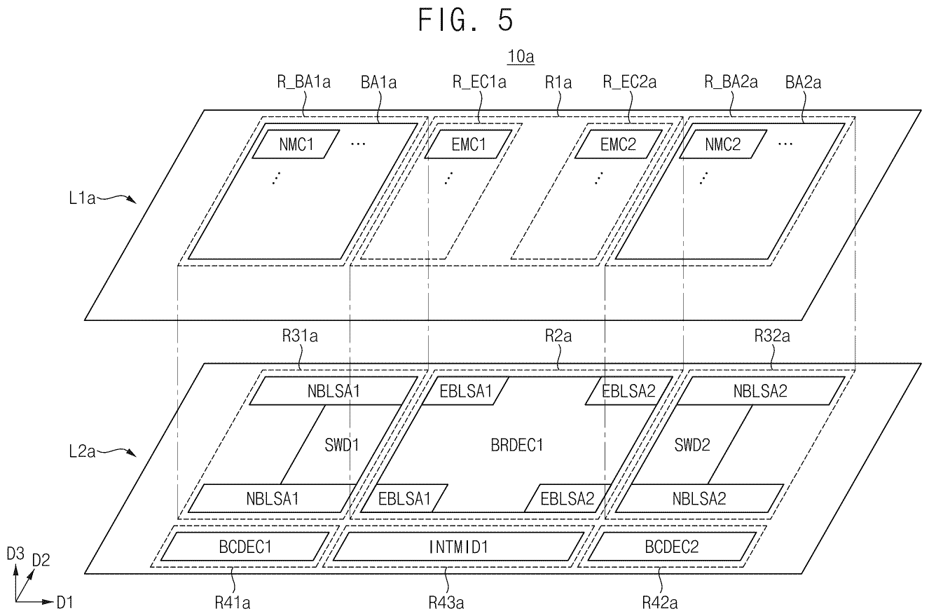

In some example embodiments, as will be described with reference to FIG. 5, the region REG2 in the second semiconductor layer L2 where the row decoder RDEC is disposed may be maintained the same as that of an existing memory device, and the region REG1 in the first semiconductor layer L1 where the plurality of ECC memory cells EMC are disposed may be moved to partially and/or completely overlap the region REG2 in the third direction D3.

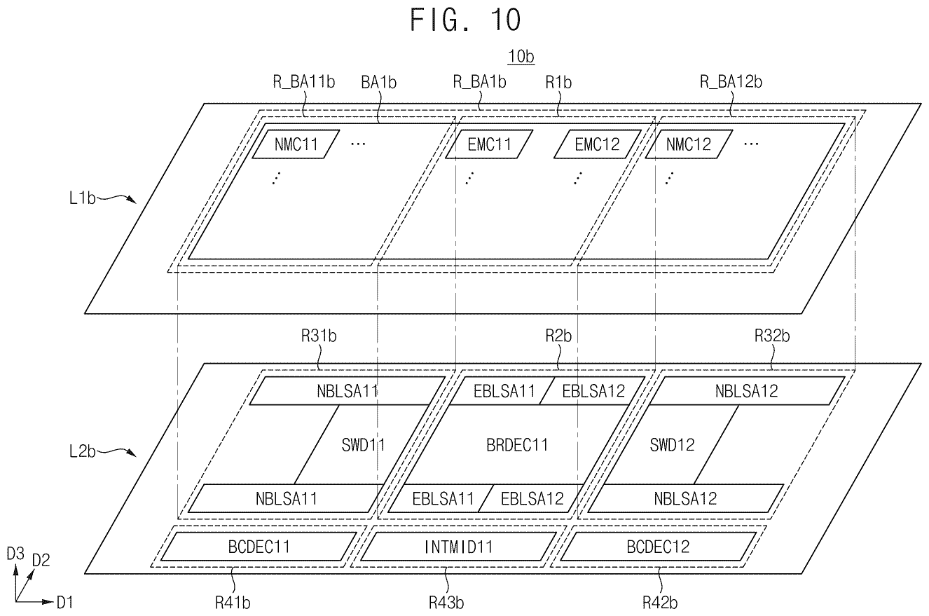

In some example embodiments, as will be described with reference to FIG. 10, the region REG1 in the first semiconductor layer L1 where the plurality of ECC memory cells EMC are disposed may be maintained the same as that of an existing memory device, and the region REG2 in the second semiconductor layer L2 where the row decoder RDEC is disposed may be moved to partially and/or completely overlap the region REG1 in the third direction D3.

The memory device 10 according to example embodiments may have or adopt a structure in which the peripheral circuit PCKT and the memory cell array MCA are stacked in the third direction D3, e.g., a cell over periphery (COP) structure in which the peripheral circuit PCKT is formed below and then the memory cell array MCA is stacked on the peripheral circuit PCKT. Accordingly, the memory device 10 may have a relatively small size.

In addition, in the memory device 10 according to example embodiments, the ECC memory cells EMC included in the memory cell array MCA and the row decoder RDEC included in the peripheral circuit PCKT may be arranged to overlap each other in the third direction D3. As a result, an area occupied by the ECC memory cells EMC in the first semiconductor layer L1 may be reduced, and/or an area occupied by the row decoder RDEC in the second semiconductor layer L2 may be reduced. Accordingly, the memory device 10 may be further reduced in size. In other words, a size gain may be obtained.

However, example embodiments are not limited thereto, and the memory device 10 may have or adopt a bonding vertical NAND (BVNAND) structure in which the memory cell array MCA includes vertical flash memory cells (e.g., vertical NAND cells) and the peripheral circuit PCKT and the memory cell array MCA are disposed or arranged in the third direction D3.

FIG. 3 is a schematic block diagram illustrating an example of a memory device according to example embodiments.

Referring to FIG. 3, a memory device 200 may include a peripheral circuit 201 and a memory cell array 300. The peripheral circuit 201 may include a control logic circuit 210, an address register 220, a bank control logic circuit 230, a row address multiplexer (RA MUX) 240, a refresh counter 245, a column address (CA) latch 250, a row decoder 260, a column decoder 270, a sense amplifier unit 285, an input/output (I/O) gating circuit 290 and a data I/O buffer 295. For example, the memory device 200 may be one of various volatile memory devices such as a dynamic random access memory (DRAM).

The memory cell array 300 may include first to eighth bank arrays 310 to 380 (e.g., first to eighth bank arrays 310, 320, 330, 340, 350, 360, 370 and 380, only the first and eighth bank arrays being explicitly shown). The row decoder 260 may include first to eighth bank row decoders 260a to 260h (only the first and eighth bank row decoders being explicitly shown) connected respectively to the first to eighth bank arrays 310 to 380. The column decoder 270 may include first to eighth bank column decoders 270a to 270h (only the first and eighth bank column decoders being explicitly shown) connected respectively to the first to eighth bank arrays 310 to 380. The sense amplifier unit 285 may include first to eighth bank sense amplifiers 285a to 285h (only the first and eighth bank sense amplifiers being explicitly shown) connected respectively to the first to eighth bank arrays 310 to 380.

The first to eighth bank arrays 310 to 380, the first to eighth bank row decoders 260a to 260h, the first to eighth bank column decoders 270a to 270h, and the first to eighth bank sense amplifiers 285a to 285h may form first to eighth banks. Each of the first to eighth bank arrays 310 to 380 may include a plurality of wordlines WL, a plurality of bitlines BL, and a plurality of memory cells MC that are at intersections of the wordlines WL and the bitlines BL.

Although FIG. 3 illustrates the memory device 200 including eight banks (and eight bank arrays, eight row decoders, and so on), the memory device 200 may include any number of banks; for example, one, two, four, eight, sixteen, or thirty two banks, or any number therebetween one and thirty two.

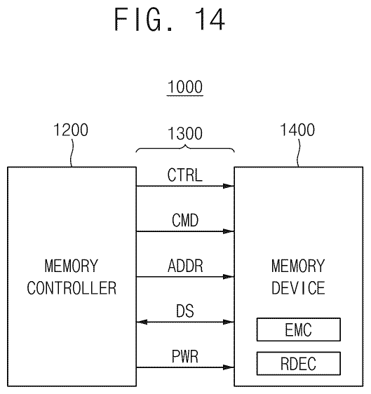

The address register 220 may receive an address ADDR supplied thereto, including a bank address BANK_ADDR, a row address ROW_ADDR, and a column address COL_ADDR, from a memory controller (e.g., a memory controller 1200 in FIG. 14). The address register 220 may provide the received bank address BANK ADDR to the bank control logic circuit 230, may provide the received row address ROW_ADDR to the row address multiplexer 240, and may provide the received column address COL_ADDR to the column address latch 250.

The bank control logic circuit 230 may generate bank control signals in response to the bank address BANK_ADDR. One of the first to eighth bank row decoders 260a to 260h corresponding to the bank address BANK_ADDR may be activated in response to the bank control signals, and one of the first to eighth bank column decoders 270a to 270h corresponding to the bank address BANK_ADDR may be activated in response to the bank control signals.

The row address multiplexer 240 may receive the row address ROW_ADDR from the address register 220, and may receive a refresh row address REF_ADDR from the refresh counter 245. The row address multiplexer 240 may selectively output the row address ROW ADDR or the refresh row address REF_ADDR as a row address RA. The row address RA that is output from the row address multiplexer 240 may be applied to the first to eighth bank row decoders 260a to 260h.

The activated one of the first to eighth bank row decoders 260a to 260h may decode the row address RA that is output from the row address multiplexer 240, and may activate in the corresponding bank array a wordline WL corresponding to the row address RA. For example, the activated bank row decoder may generate a wordline driving voltage, and may apply the wordline driving voltage to the wordline WL corresponding to the row address RA.

The column address latch 250 may receive the column address COL_ADDR from the address register 220, and may temporarily store the received column address COL_ADDR. In some example embodiments, in a burst mode, the column address latch 250 may generate column addresses that increment from the received column address COL_ADDR. The column address latch 250 may apply the temporarily stored or generated column address to the first to eighth bank column decoders 270a to 270h.

The activated one of the first to eighth bank column decoders 270a to 270h may decode the column address COL_ADDR that is output from the column address latch 250, and may control the I/O gating circuit 290 to output data corresponding to the column address COL_ADDR.

The I/O gating circuit 290 may include circuitry configured to gate input/output data. The I/O gating circuit 290 may further include read data latches configured to store data that is output from the first to eighth bank arrays 310 to 380 (e.g., during a read operation), and may also include write control devices for writing data to the first to eighth bank arrays 310 to 380 (e.g., during a write operation).

Data DAT read from one of the first to eighth bank arrays 310 to 380 may be sensed by a corresponding one of the sense amplifiers 285 connected to the one bank array from which the data DAT is to be read, and may be stored in the read data latches. The data DAT stored in the read data latches may be provided to the memory controller via the data I/O buffer 295. Data DAT to be written in one of the first to eighth bank arrays 310 to 380 may be provided to the I/O gating circuit 290 via the data I/O buffer 295 from the memory controller, and the I/O gating circuit 290 may write the data DAT in the one bank array through the write drivers.

The control logic circuit 210 may control operations of the memory device 200. For example, the control logic circuit 210 may generate control signals for the memory device 200 to perform the write operation and/or the read operation. The control logic circuit 210 may include a command decoder 211 that decodes a command CMD received from the memory controller, and a mode register 212 that sets an operation mode of the memory device 200. In some example embodiments, operations described herein as being performed by the control logic circuit 210 may be performed by processing circuitry. For example, the command decoder 211 may generate the control signals corresponding to the command CMD by decoding a write enable signal, a row address strobe signal, a column address strobe signal, a chip selection signal, etc.

The row decoder RDEC in FIG. 2 may correspond to the row decoder 260, and the column decoder CDEC in FIG. 2 may correspond to the column decoder 270. The bitline sense amplifiers BLSA in FIG. 2 may be included in the sense amplifier unit 285, and the sub-wordline drivers SWD in FIG. 2 may be disposed between the row decoder 260 and the memory cell array 300 and may control the driving of the wordlines WL. In some example embodiments, one bank row decoder and/or one bank column decoder may be shared by two or more bank arrays.

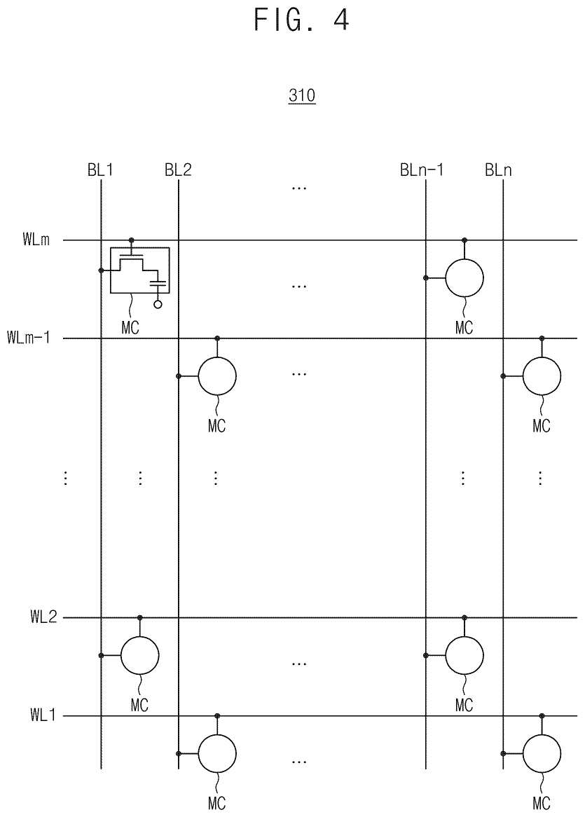

FIG. 4 is a schematic diagram illustrating an example of a memory cell array that may be included in the memory device 200 of FIG. 3.

Referring to FIGS. 3 and 4, the first bank array 310 included in the memory cell array 300 may include a plurality of wordlines WL1, WL2, . . . , WLm−1, WLm (where m is a positive integer greater than or equal to two), a plurality of bitlines BL1, BL2, . . . , BLn−1, BLn (where n is a positive integer greater than or equal to two that may or may not be the same as m), and a plurality of memory cells MC arranged at or near intersections between the wordlines WL1 to WLm and the bitlines BL1 to BLn. For example, each of the plurality of memory cells MC may include a DRAM cell structure. The plurality of wordlines WL1 to WLm to which the plurality of memory cells MC are connected may be referred to as rows of the first bank array 310, and the plurality of bitlines BL1 to BLn to which the plurality of memory cells MC are connected may be referred to as columns of the first bank array 310.

The normal memory cells NMC and the ECC memory cells EMC in FIG. 2 may correspond to the plurality of memory cells MC. For example, some of the memory cells MC may operate as the normal memory cells NMC, and the other of the memory cells MC may operate as the ECC memory cells EMC.

Although the memory device according to example embodiments is described based on a DRAM, the memory device according to example embodiments may be any volatile memory device, and/or any nonvolatile memory device, e.g., a static random access memory (SRAM), a flash memory, a phase-change random access memory (PRAM), a resistive random access memory (RRAM), a magnetic random access memory (MRAM), a ferroelectric random access memory (FRAM), or the like.

FIG. 5 is a schematic perspective view of at least a portion of the example memory device of FIG. 1.

Referring to FIG. 5, a memory device 10a includes a first semiconductor layer L1a and a second semiconductor layer L2a. The first semiconductor layer L1a in FIG. 5 may correspond to the first semiconductor layer L1 in FIG. 1, and likewise the second semiconductor layer L2a in FIG. 5 may correspond to the second semiconductor layer L2 in FIG. 1. The descriptions repeated with or overlapping with descriptions of FIG. 1 will be omitted in the interest of brevity.

The first semiconductor layer L1a may include a first bank array BA1a and a second bank array BA2a. The first bank array BA1a may include first normal memory cells NMC1 that store first normal data. The second bank array BA2a may include second normal memory cells NMC2 that store second normal data.

The first semiconductor layer L1a may include first ECC memory cells EMC1 and second ECC memory cells EMC2. The first ECC memory cells EMC1 may correspond to the first normal memory cells NMC1, and may store first ECC data associated with the first normal data. The second ECC memory cells EMC2 may correspond to the second normal memory cells NMC2, and may store second ECC data associated with the second normal data.

The first and second bank arrays BA1a and BA2a may be included in the memory cell array MCA in FIGS. 1 and 2, and each of the first and second bank arrays BA1a and BA2a may correspond to one of the bank arrays 310 to 380 in FIG. 3. The first and second normal memory cells NMC1 and NMC2 may be included in the plurality of normal memory cells NMC in FIGS. 1 and 2. The first and second ECC memory cells EMC1 and EMC2 may be included in the plurality of ECC memory cells EMC in FIGS. 1 and 2.

The first bank array BA1a may be disposed in a first bank array region R_BA1a in the first semiconductor layer L1a, and the second bank array BA2a may be disposed in a second bank array region R_BA2a in the first semiconductor layer L1a. The first and second bank arrays BA1a and BA2a may be arranged to be spaced apart from each other in the first direction D1, and a first region R1a may exist between the first and second bank arrays BA1a and BA2a.

The first ECC memory cells EMC1 may be disposed in a first ECC cell region R_EC1a included in the first region R1a in the first semiconductor layer L1a, and the second ECC memory cells EMC2 may be disposed in a second ECC cell region R_EC2a included in the first region R1a in the first semiconductor layer L1a. For example, the first ECC cell region R_EC1a may be formed in the first region R1a to be adjacent to the first bank array BA1a (e.g., adjacent to the first bank array region R_BA1a), and the second ECC cell region R_EC2a may be formed in the first region R1a to be adjacent to the second bank array BA2a (e.g., adjacent to the second bank array region R_BA2a).

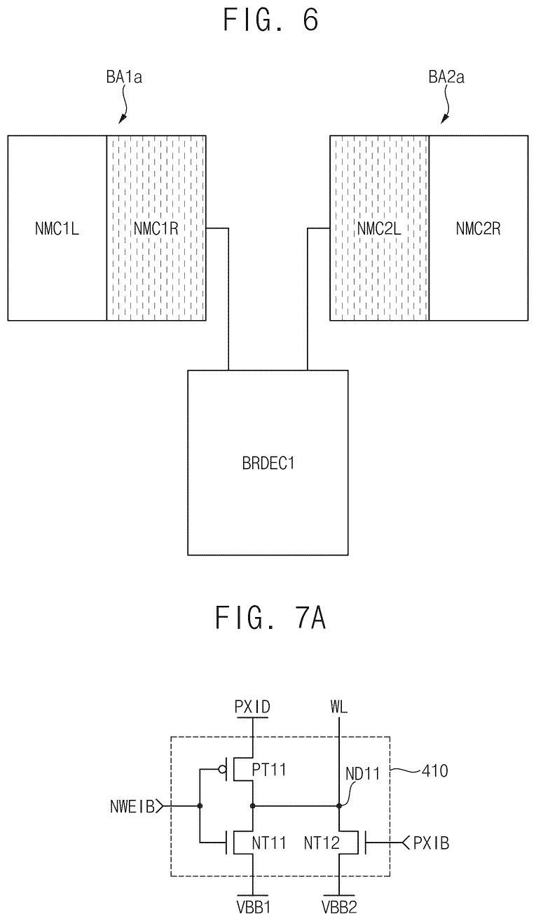

The second semiconductor layer L2a may include a first bank row decoder BRDEC1. The first bank row decoder BRDEC1 may drive the first and second normal memory cells NMC1 and NMC2 (e.g., the first and second bank arrays BA1a and BA2a), and may drive the first and second ECC memory cells EMC1 and EMC2. For example, as will be described with reference to FIG. 6, the first bank row decoder BRDEC1 may drive parts of the first and second normal memory cells NMC1 and NMC2.

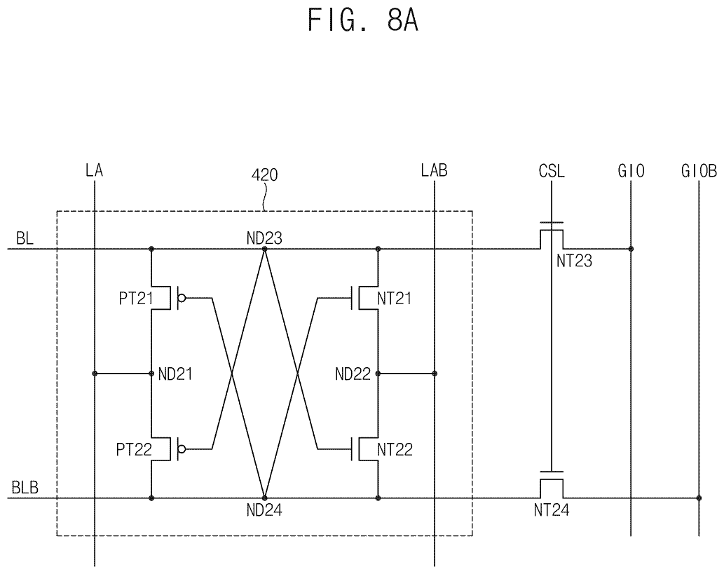

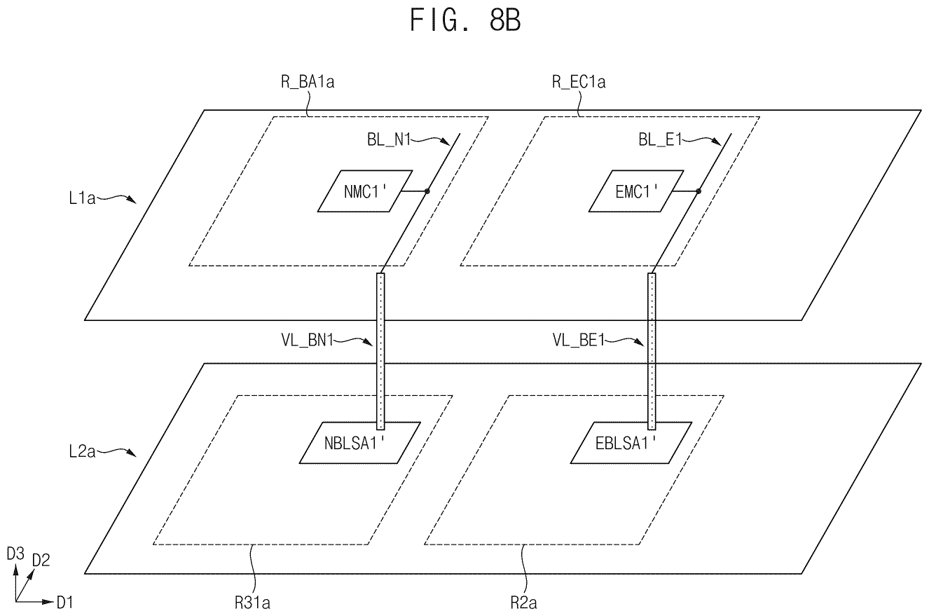

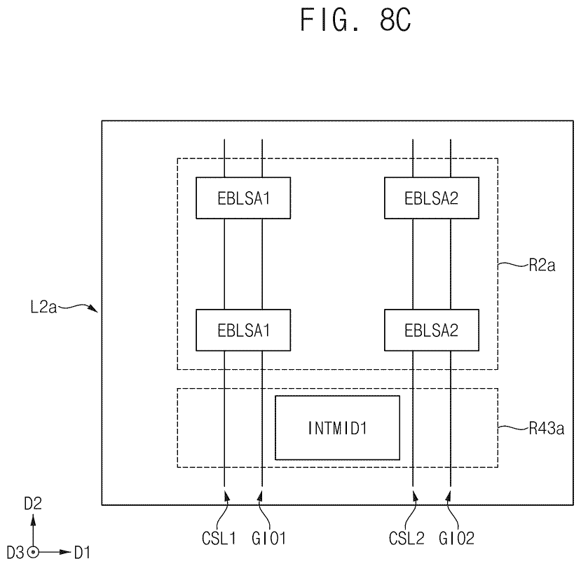

The second semiconductor layer L2a may include first normal bitline sense amplifiers NBLSA1, second normal bitline sense amplifiers NBLSA2, first ECC bitline sense amplifiers EBLSA1 and second ECC bitline sense amplifiers EBLSA2. The first normal bitline sense amplifiers NBLSA1 may drive the first normal memory cells NMC1, and the second normal bitline sense amplifiers NBLSA2 may drive the second normal memory cells NMC2. The first ECC bitline sense amplifiers EBLSA1 may drive the first ECC memory cells EMC1, and the second ECC bitline sense amplifiers EBLSA2 may drive the second ECC memory cells EMC2. An example of each sense amplifier will be described with reference to FIG. 8A.

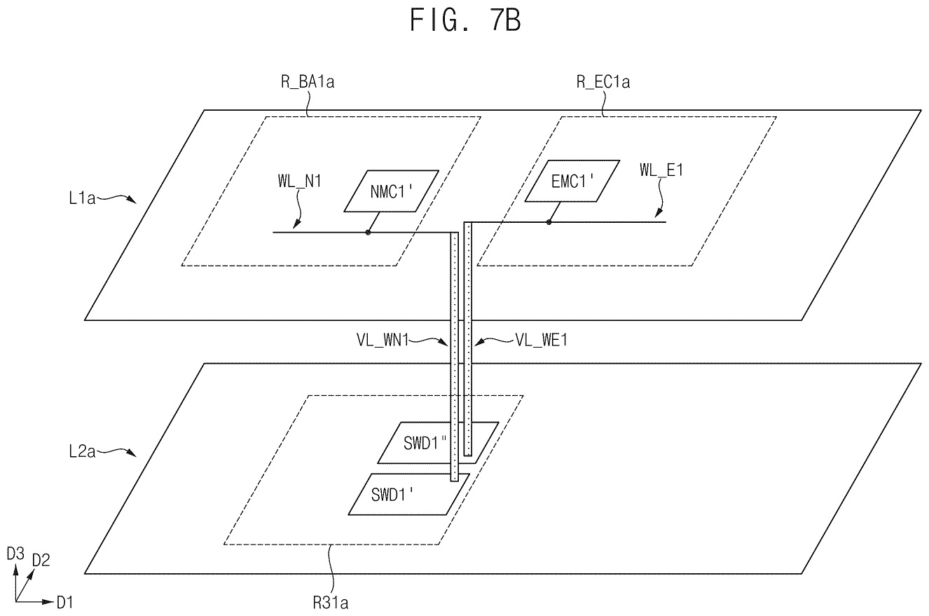

The second semiconductor layer L2a may include first sub-wordline drivers SWD1 and second sub-wordline drivers SWD2. The first sub-wordline drivers SWD1 may drive the first normal memory cells NMC1 and the first ECC memory cells EMC1, and may be shared by the first normal memory cells NMC1 and the first ECC memory cells EMC1. The second sub-wordline drivers SWD2 may drive the second normal memory cells NMC2 and the second ECC memory cells EMC2, and may be shared by the second normal memory cells NMC2 and the second ECC memory cells EMC2. An example of each sub-wordline driver will be described with reference to FIG. 7A.

The second semiconductor layer L2a may include a first bank column decoder BCDEC1, a second bank column decoder BCDEC2 and a first intermediate circuit INTMID1. The first bank column decoder BCDEC1 may drive the first normal memory cells NMC1 and the first ECC memory cells EMC1, and the second bank column decoder BCDEC2 may drive the second normal memory cells NMC2 and the second ECC memory cells EMC2. The first intermediate circuit INTMID1 may be connected to the first bank row decoder BRDEC1, and may be used to drive the first and second normal memory cells NMC1 and NMC2 and the first and second ECC memory cells EMC1 and EMC2.

The first bank row decoder BRDEC1 may be included in the row decoder RDEC in FIGS. 1 and 2, and may correspond to one of the bank row decoders 260a to 260h in FIG. 3. The first and second normal bitline sense amplifiers NBLSA1 and NBLSA2 and the first and second ECC bitline sense amplifiers EBLSA1 and EBLSA2 may be included in the bitline sense amplifiers BLSA in FIG. 2, and may be included in the sense amplifier unit 285 in FIG. 3. The first and second sub-wordline drivers SWD1 and SWD2 may be included in the sub-wordline drivers SWD in FIG. 2, may be disposed between the row decoder 260 and the memory cell array 300 in FIG. 3, and may be used to drive the wordlines WL in FIG. 3. The first and second bank column decoders BCDEC1 and BCDEC2 may be included in the column decoder CDEC in FIG. 2 and each of the first and second bank column decoders BCDEC1 and BCDEC2 may correspond to one of the bank column decoders 270a to 270h in FIG. 3. The first intermediate circuit INTMID1 may correspond to at least a portion of a front end (e.g., the control logic circuit 210, the address register 220, the bank control logic circuit 230, the row address multiplexer 240, etc.) of the bank row decoders 260a to 260h in FIG. 3. For example, the first intermediate circuit INTMID1 may include a repeater, a control logic, etc.

The first bank row decoder BRDEC1 may be disposed in a second region R2a in the second semiconductor layer L2a that overlaps the first region R1a in the first semiconductor layer L1a in the third direction D3. Thus, the first bank row decoder BRDEC1 may be disposed below the first and second ECC memory cells EMC1 and EMC2, and the first and second ECC memory cells EMC1 and EMC2 and the first bank row decoder BRDEC1 may be arranged to overlap each other in the third direction D3. For example, when the first and second semiconductor layers L1a and L2a are overlapped and viewed on the same plane, the first region R1a and the second region R2a may coincide and may be substantially the same as each other. Although FIG. 5 illustrates an example where the first region R1a and the second region R2a completely overlap, example embodiments are not limited thereto, and the first region R1a and the second region R2a may partially overlap in the third direction D3.

The first and second ECC bitline sense amplifiers EBLSA1 and EBLSA2 may be disposed in the second region R2a in the second semiconductor layer L2a. Thus, the first and second ECC bitline sense amplifiers EBLSA1 and EBLSA2 may be disposed below the first and second ECC memory cells EMC1 and EMC2. For example, the first and second ECC bitline sense amplifiers EBLSA1 and EBLSA2 may be disposed at or adjacent to at least one edge and/or at least one corner of the second region R2a in the second semiconductor layer L2a.

The first normal bitline sense amplifiers NBLSA1 and the first sub-wordline drivers SWD1 may be disposed in a region R31a in the second semiconductor layer L2a that overlaps the first bank array region R_BA1a in the first semiconductor layer L1a in the third direction D3. Thus, the first normal bitline sense amplifiers NBLSA1 and the first sub-wordline drivers SWD1 may be disposed below the first normal memory cells NMC1 (e.g., below the first bank array BA1a). For example, the region R31a may be formed adjacent to a first side of the second region R2a.

The second normal bitline sense amplifiers NBLSA2 and the second sub-wordline drivers SWD2 may be disposed in a region R32a in the second semiconductor layer L2a that overlaps the second bank array region R_BA2a in the first semiconductor layer L1a in the third direction D3. Thus, the second normal bitline sense amplifiers NBLSA2 and the second sub-wordline drivers SWD2 may be disposed below the second normal memory cells NMC2 (e.g., below the second bank array BA2a). For example, the region R32a may be formed adjacent to a second side of the second region R2a that is opposite to the first side of the second region R2a.

Connections of the sub-wordline drivers SWD1 and SWD2, the memory cells NMC1, NMC2, EMC1 and EMC2, and lines will be described with reference to FIG. 7B, and connections of the bitline sense amplifiers NBLSA1, NBLSA2, EBLSA1 and EBLSA2, the memory cells NMC1, NMC2, EMC1 and EMC2, and lines will be described with reference to FIGS. 8B and 8C.

The first bank column decoder BCDEC1 may be disposed in a first bank column decoder region R41a in the second semiconductor layer L2a, and the second bank column decoder BCDEC2 may be disposed in a second bank column decoder region R42a in the second semiconductor layer L2a. For example, the first bank column decoder region R41a may be formed adjacent to the region R31a in the second direction D2 where the first normal bitline sense amplifiers NBLSA1 and the first sub-wordline drivers SWD1 are disposed, and the second bank column decoder region R42a may be formed adjacent to the region R32a in the second direction D2 where the second normal bitline sense amplifiers NBLSA2 and the second sub-wordline drivers SWD2 are disposed.

The first intermediate circuit INTMID1 may be disposed in a region R43a in the second semiconductor layer L2a. For example, the region R43a may be formed adjacent to the second region R2a in the second direction D2 and adjacent to the bank column decoder regions R41a and R42a in the first direction D1. For example, the region R43a may be disposed at a location that intersects when the bank column decoder regions R41a and R42a are extended in the first direction D1 and the second region R2a is extended in the second direction D2.

Conventionally, the first region R1a between adjacent bank arrays BA1a and BA2a in the first semiconductor layer L1a was an empty space, ECC memory cells were disposed in the bank arrays BA1a and BA2a, and the first bank row decoder BRDEC1 was disposed in the second region R2a in the second semiconductor layer L2a that is below the first region R1a. In the memory device 10a according to example embodiments, positions (or locations) of the ECC memory cells EMC1 and EMC2 may be moved to the first region R1a that overlaps the second region R2a. In addition, positions of the ECC bitline sense amplifiers EBLSA1 and EBLSA2 for driving the ECC memory cells EMC1 and EMC2 may be moved to the second region R2a. Accordingly, a size of the memory device 10a may be reduced.

Although FIG. 5 illustrates an example of arrangements of two bank arrays BA1a and BA2a and related components, example embodiments are not limited thereto. For example, a plurality of bank arrays may be arranged to be spaced apart along the first direction D1, ECC memory cells may be disposed between the bank arrays, and bank row decoders may be disposed below the ECC memory cells between the bank arrays. In addition, the above-described bank arrays arranged along the first direction D1 may form one bank group, a plurality of bank groups may be arranged along the second direction D2, and ECC memory cells and bank row decoders may be disposed similar to those described above.

FIGS. 6, 7A, 7B, 8A, 8B, 8C and 9 are schematic diagrams for describing the example memory device of FIG. 5.

Referring to FIG. 6, an example where the first bank row decoder BRDEC1 drives the first and second bank arrays BA1a and BA2a is illustrated.

The first bank array BA1a may include first normal memory cells NMC1L and NMC1R disposed in a left-half region and a right-half region, respectively, of the first bank array BA1a, and the second bank array BA2a may include second normal memory cells NMC2L and NCM2R disposed in a left-half region and a right-half region, respectively, of the second bank array BA2a.

More particularly, first parts NMC1R of the first normal memory cells NMC1L and NMC1R may be disposed in a partial region (e.g., right-half region) of the first bank array BA1a, and second parts NMC1L of the first normal memory cells NMC1L and NMC1R may be disposed in another partial region (e.g., left-half region) of the first bank array BA1a. Similarly, first parts NMC2L of the second normal memory cells NMC2L and NCM2R may be disposed in a partial region (e.g., left-half region) of the second bank array BA2a, and second parts NMC2R of the second normal memory cells NMC2L and NCM2R may be disposed in another partial region (e.g., right-half region) of the second bank array BA2a.

The first bank row decoder BRDEC1 may be connected only to the first parts NMC1R of the first normal memory cells NMC1L and NMC1R and the first parts NMC2L of the second normal memory cells NMC2L and NCM2R, and may drive only the first parts NMC1R of the first normal memory cells NMC1L and NMC1R and the first parts NMC2L of the second normal memory cells NMC2L and NCM2R. For example, the first parts NMC1R of the first normal memory cells NMC1L and NMC1R may be right-half normal memory cells adjacent to the first region R1a in FIG. 5 among the first normal memory cells NMC1L and NMC1R, and the first parts NMC2L of the second normal memory cells NMC2L and NCM2R may be left-half normal memory cells adjacent to the first region R1a in FIG. 5 among the second normal memory cells NMC2L and NCM2R. For example, the first ECC memory cells EMC1 in the first region R1a in FIG. 5 may be ECC memory cells corresponding to the first parts NMC1R of the first normal memory cells NMC1L and NMC1R, and the second ECC memory cells EMC2 in the first region R1a in FIG. 5 may be ECC memory cells corresponding to the first parts NMC2L of the second normal memory cells NMC2L and NCM2R.

Although not illustrated in detail, ECC memory cells corresponding to the second parts NMC1L of the first normal memory cells NMC1L and NMC1R may be disposed adjacent to the left side of the first bank array BA1a, and a bank row decoder that drives the second parts NMC1L of the first normal memory cells NMC1L and NMC1R and the corresponding ECC memory cells may be disposed below the corresponding ECC memory cells. Similarly, ECC memory cells corresponding to the second parts NMC2R of the second normal memory cells NMC2L and NCM2R may be disposed adjacent to the right side of the second bank array BA2a, and a bank row decoder that drives the second parts NMC2R of the second normal memory cells NMC2L and NCM2R and the corresponding ECC memory cells may be disposed below the corresponding ECC memory cells.

Referring to FIG. 7A, an example of a schematic circuit structure of each of the sub-wordline drivers SWD1 and SWD2 is illustrated, according to one or more embodiments.

A sub-wordline driver 410 may be connected to the wordline WL, and may have a circuit structure for driving the wordline WL. For example, the sub-wordline driver 410 may include transistors PT11, NT11 and NT12 that are connected to the wordline WL through a node ND11.

The transistor PT11 may be connected between a driving signal PXID and the node ND11, and may pull up the wordline WL to a voltage level of the driving signal PXID in response to a wordline enable signal NWE1B. The transistor NT11 may be connected between the node ND11 and a first negative voltage VBB1, and may pull down the wordline WL to a voltage level of the first negative voltage VBB1 in response to the wordline enable signal NWEIB. The transistor NT12 may be connected between the node ND11 and a second negative voltage VBB2, and may maintain the wordline WL at a voltage level of the second negative voltage VBB2 when the wordline WL is deactivated. For example, the transistor NT12 may switch between a source provided with the second negative voltage VBB2 and a drain connected to the wordline WL in response to a driving signal PXIB, which is complementary to the driving signal PXID. When the driving signal PXIB is a logic high level, transistor NT12 will turn on thereby maintaining the wordline WL (and node ND11) at the second negative voltage level VBB2. For example, the driving signals PXID and PXIB, the wordline enable signal NWEIB and the negative voltages VBB1 and VBB2 may be provided from an external voltage generator.

In some example embodiments, the transistor PT11 may be a p-type metal oxide semiconductor (PMOS) transistor, and each of the transistors NT11 and NT12 may be an n-type metal oxide semiconductor (NMOS) transistor. For example, the transistor PT11, NT11 and NT12 may be referred to as a pull-up transistor, a pull-down transistor and a keeping transistor, respectively.

However, example embodiments are not limited thereto, and each sub-wordline driver is not limited to the structure illustrated in FIG. 7A.

Referring to FIG. 7B, an example of a connection between a first normal memory cell NMC1′ and a first sub-wordline driver SWD1′ and a connection between a first ECC memory cell EMC1′ and a first sub-wordline driver SWD1″ is illustrated.

The first normal memory cell NMC1′ in the first bank array region R_BA1a in the first semiconductor layer L1a and the first sub-wordline driver SWD1′ in the region R31a in the second semiconductor layer L2a may be electrically connected to each other through a vertical line (or wire) VL_WN1 extending in the third direction D3 and a wordline WL_N1 extending in the first direction D1.

The first ECC memory cell EMC1′ in the first ECC cell region R_EC1a in the first region R1a in the first semiconductor layer L1a and the first sub-wordline driver SWD1″ in the region R31a in the second semiconductor layer L2a may be electrically connected to each other through a vertical line (or wire) VL_WE1 extending in the third direction D3 and a wordline WL_E1 extending in the first direction D1.

With respect to the vertical lines VL_WN1 and VL_WE1, a direction in which the wordline WL_N1 connected to the first normal memory cell NMC1′ extends and a direction in which the wordline WL_E1 connected to the first ECC memory cell EMC1′ extends may be opposite to each other. For example, intersections of the vertical lines VL_WN1 and VL_WE1 and the wordlines WL_N1 and WL_E1 may be arranged between the first bank array region R_BA1a and the first ECC cell region R_EC1a, and with respect to the intersections, the wordline WL_N1 may extend to the left and the wordline WL_E1 may extend to the right. In other words, the wordlines VL_WN1 and VL_WE1 may be implemented in the form of spreading both arms based on the intersections.

In some example embodiments, each of the vertical lines VL_WN1 and VL_WE1 may include the bonding pads PD_L1 and PD_L2 and the contacts CT_L1 and CT_L2 in FIG. 2.

The first normal memory cell NMC1′, the first ECC memory cell EMC1′ and the first sub-wordline drivers SWD1′ and SWD1″ may be included in the first normal memory cells NMC1, the first ECC memory cells EMC1 and the first sub-wordline drivers SWD1 in FIG. 5, respectively. Connections between the first normal memory cells NMC1 and first parts of the first sub-wordline drivers SWD1 in FIG. 5 may be substantially the same as the connection between the first normal memory cell NMC1′ and the first sub-wordline driver SWD1′, and connections between the first ECC memory cells EMC1 and second parts of the first sub-wordline drivers SWD1 in FIG. 5 may be substantially the same as the connection between the first ECC memory cell EMC1′ and the first sub-wordline driver SWD1″.

Although not illustrated in detail, connections between the second normal and ECC memory cells NMC2 and EMC2 and the second sub-wordline drivers SWD2 may be substantially the same as the connections between the first normal and ECC memory cells NMC1 and EMC1 and the first sub-wordline drivers SWD1 described above.

Referring to FIG. 8A, an example of a schematic circuit structure of each of the bitline sense amplifiers NBLSA1, NBLSA2, EBLSA1 and EBLSA2 is illustrated, according to one or more embodiments.

A bitline sense amplifier 420 may be connected to the bitline BL, and may have a circuit structure for driving the bitline BL. For example, the bitline sense amplifier 420 may include transistors PT21, PT22, NT21 and NT22 that are connected to a control line LA and a complementary control line LAB through nodes ND21 and ND22, respectively, and are connected to the bitline BL and a complementary bitline BLB through nodes ND23 and ND24, respectively.

The transistor PT21 may be connected between the nodes ND23 and ND21, and may have a gate electrode connected to the node ND24. The transistor PT22 may be connected between the nodes ND21 and ND24, and may have a gate electrode connected to the node ND23. The transistor NT21 may be connected between the nodes ND23 and ND22, and may have a gate electrode connected to the node ND24. The transistor NT22 may be connected between the nodes ND22 and ND24, and may have a gate electrode connected to the node ND23. Depending on operations of turning on and/or off the transistors PT21, PT22, NT21 and NT22 included in the bitline sense amplifier 420, various operations for the bitline BL, such as a precharge operation, an offset cancellation operation, a charge sharing operations, developing and sensing operations, etc., may be performed.

In addition, the bitline BL and the complementary bitline BLB may be connected to a global input/output (I/O) line GIO and a complementary global I/O line GIOB through transistors NT23 and NT24, respectively. Gate electrodes of the transistors NT23 and NT24 may be connected to a column selection line CSL. When the transistors NT23 and NT24 are turned on, sensed data may be output.

In some example embodiments, each of the transistors PT21 and PT22 may be a PMOS transistor, and each of the transistors NT21, NT22, NT23 and NT24 may be an NMOS transistor. However, example embodiments are not limited thereto, and each bitline sense amplifier is not limited to the structure illustrated in FIG. 8A.

Referring to FIG. 8B, an example of a connection between a first normal memory cell NMC1′ and a first normal bitline sense amplifier NBLSA1′ and a connection between a first ECC memory cell EMC1′ and a first ECC bitline sense amplifier EBLSA1′ is illustrated, according to one or more embodiments.

The first normal memory cell NMC1′ in the first bank array region R_BA1a in the first semiconductor layer L1a and the first normal bitline sense amplifier NBLSA1′ in the region R31a in the second semiconductor layer L2a may be electrically connected to each other through a vertical line (or wire) VL_BN1 extending in the third direction D3 and a bitline BL_N1 extending in the second direction D2.

The first ECC memory cell EMC1′ in the first ECC cell region R_EC1a in the first region R1a in the first semiconductor layer L1a and the first ECC bitline sense amplifier EBLSA1′ in the second region R2a in the second semiconductor layer L2a may be electrically connected to each other through a vertical line VL_BE1 extending in the third direction D3 and a bitline BL_E1 extending in the second direction D2.

In some example embodiments, each of the vertical lines VL_BN1 and VL_BE1 may include the bonding pads PD_L1 and PD_L2 and the contacts CT_L1 and CT_L2 in FIG. 2.

The first normal memory cell NMC1′, the first ECC memory cell EMC1′, the first normal bitline sense amplifier NBLSA1′ and the first ECC bitline sense amplifier EBLSA1′ may be included in the first normal memory cells NMC1, the first ECC memory cells EMC1, the first normal bitline sense amplifiers NBLSA1 and the first ECC bitline sense amplifiers EBLSA1 in FIG. 5, respectively. Connections between the first normal memory cells NMC1 and the first normal bitline sense amplifiers NBLSA1 in FIG. 5 may be substantially the same as the connection between the first normal memory cell NMC1′ and the first normal bitline sense amplifier NBLSA1′, and connections between the first ECC memory cells EMC1 and the first ECC bitline sense amplifiers EBLSA1 in FIG. 5 may be substantially the same as the connection between the first ECC memory cell EMC1′ and the first ECC bitline sense amplifier EBLSA1′.

Although not illustrated in detail, connections between the second normal and ECC memory cells NMC2 and EMC2 and the second normal and ECC bitline sense amplifiers NBLSA2 and EBLSA2 may be substantially the same as the connections between the first normal and ECC memory cells NMC1 and EMC1 and the first normal and ECC bitline sense amplifiers NBLSA1 and EBLSA1 described above.

Referring to FIG. 8C, an example of a connection between the first and second ECC bitline sense amplifiers EBLSA1 and EBLSA2 and lines CSL1, GIO1, CSL2 and GIO2 is illustrated, according to one or more embodiments.

In the second semiconductor layer L2a, a first column selection line CSL1 and a first global I/O line GIO1 that are connected to the first ECC bitline sense amplifiers EBLSA1 in the second region R2a and a second column selection line CSL2 and a second global I/O line GIO2 connected to the second ECC bitline sense amplifiers EBLSA2 in the second region R2a may be formed in an empty space in the region R43a. For example, the first column selection line CSL1 and the first global I/O line GIO1 may be disposed in an empty space to the left of the first intermediate circuit INTMID1 in the region R43a, and the second column selection line CSL2 and the second global I/O line GIO2 may be disposed in an empty space to the right of the first intermediate circuit INTMID1 in the region R43a.

Although not illustrated in detail, I/O sense amplifiers, global I/O line drivers and/or MDLs that drive the first and second ECC memory cells EMC1 and EMC2 may be formed in an empty space in the region R43a.

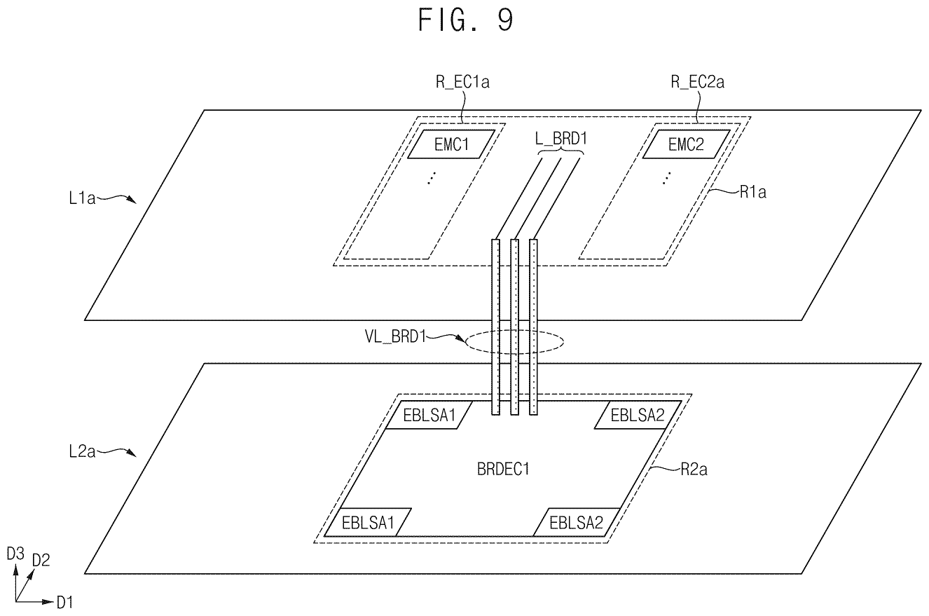

Referring to FIG. 9, an example of a connection between the first bank row decoder BRDEC1 and lines L_BRD1 is illustrated, according to one or more embodiments.

The lines L_BRD1 connected to the first bank row decoder BRDEC1 in the second region R2a in the second semiconductor layer L2a may be disposed in a region other than the first and second ECC cell regions R_EC1a and R_EC2a in the first region R1a in the first semiconductor layer L1a. For example, the lines L_BRD1 connected to the first bank row decoder BRDEC1 may be disposed between the first and second ECC cell regions R_EC1a and R_EC2a in the first region R1a in the first semiconductor layer L1a. In other words, the ECC memory cells EMC1 and EMC2 may be disposed in a portion of the first region R1a first, and then the remaining region in the first region R1a may be used as a bussing region.

For example, the first bank row decoder BRDEC1 and the lines L_BRD1 may be electrically connected through vertical lines VL_BRD1. For example, each of the vertical lines VL_BRD1 may include the bonding pads PD_L1 and PD_L2 and the contacts CT_L1 and CT_L2 in FIG. 2. For example, the first bank row decoder BRDEC1 may be connected to other components of the memory device through the lines L_BRD1.

FIG. 10 is a schematic perspective view of at least a portion of the example memory device 10 of FIG. 1.

Referring to FIG. 10, a memory device 10b includes a first semiconductor layer L1b and a second semiconductor layer L2b stacked in the third direction D3. The descriptions repeated with or overlapping with descriptions of FIGS. 1 and 5 will be omitted in the interest of brevity.

The first semiconductor layer L1b may include a first bank array BA1b. The first bank array BA1b may include first normal memory cells NMC11 and NMC12 that store first normal data.

The first semiconductor layer L1b may include first ECC memory cells EMC11 and EMC12. The first ECC memory cells EMC11 and EMC12 may correspond to the first normal memory cells NMC11 and NMC12, respectively, and may store first ECC data associated with the first normal data.

The first bank array BA1b may be included in the memory cell array MCA in FIGS. 1 and 2, and may correspond to one of the bank arrays 310 to 380 in FIG. 3. The first normal memory cells NMC11 and NMC12 may be included in the plurality of normal memory cells NMC in FIGS. 1 and 2. The first ECC memory cells EMC11 and EMC12 may be included in the plurality of ECC memory cells EMC in FIGS. 1 and 2.

The first bank array BA1b may be disposed in a first bank array region R_BA1b in the first semiconductor layer L1b. The first normal memory cells NMC11 may be disposed in a first sub-region R_BA11b in the first bank array region R_BA1b, and the first normal memory cells NMC12 may be disposed in a second sub-region R_BA12b in the first bank array region R_BA1b. For example, the first and second sub-regions R_BA11b and R_BA12b may be arranged to be spaced apart from each other in the first direction D1.

The first ECC memory cells EMC11 and EMC12 may be disposed in a first region R1b included in the first bank array region R_BA1b in the first semiconductor layer L1b. For example, the first region R1b may be formed at or adjacent to a center of the first bank array region R_BA1b between the first and second sub-regions R_BA11b and R_BA12b. For example, the first ECC memory cells EMC11 may be disposed in the first region R1b to correspond to and be adjacent to the first normal memory cells NMC11 (e.g., adjacent to the first sub-region R_BA11b), and the first ECC memory cells EMC12 may be disposed in the first region R1b to correspond to and be adjacent to the first normal memory cells NMC12 (e.g., adjacent to the second sub-region R_BA12b).

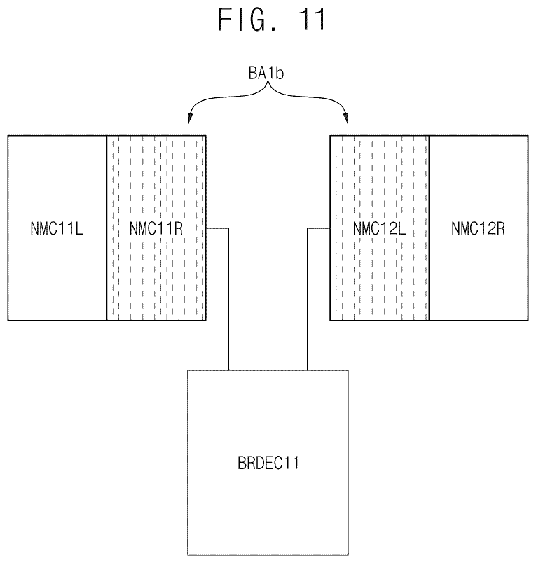

The second semiconductor layer L2b may include a first bank row decoder BRDEC11. The first bank row decoder BRDEC11 may drive the first normal memory cells NMC11 and NMC12 and the first ECC memory cells EMC11 and EMC12 (e.g., may drive the first bank array BA1b). For example, as will be described with reference to FIG. 11, the first bank row decoder BRDEC11 may drive parts of the first normal memory cells NMC11 and NMC12.

The second semiconductor layer L2b may include first normal bitline sense amplifiers NBLSA11 and NBLSA12 and first ECC bitline sense amplifiers EBLSA11 and EBLSA12. The first normal bitline sense amplifiers NBLSA11 and NBLSA12 may drive the first normal memory cells NMC11 and NMC12, respectively. The first ECC bitline sense amplifiers EBLSA11 and EBLSA12 may drive the first ECC memory cells EMC11 and EMC12, respectively.

The second semiconductor layer L2b may include first sub-wordline drivers SWD11 and SWD12. The first sub-wordline drivers SWD11 and SWD12 may drive the first normal memory cells NMC11 and NMC12 and the first ECC memory cells EMC11 and EMC12, and may be shared by the first normal memory cells NMC11 and NMC12 and the first ECC memory cells EMC11 and EMC12.

The second semiconductor layer L2b may include first bank column decoders BCDEC11 and BCDEC12 and a first intermediate circuit INTMID11. The first bank column decoder BCDEC11 and BCDEC12 may drive the first normal memory cells NMC11 and NMC12 and the first ECC memory cells EMC11 and EMC12. The first intermediate circuit INTMID11 may be connected to the first bank row decoder BRDEC11, and may be used to drive the first normal memory cells NMC11 and NMC12 and the first ECC memory cells EMC11 and EMC12.

The first bank row decoder BRDEC11 may be included in the row decoder RDEC in FIGS. 1 and 2, and may correspond to one of the bank row decoders 260a to 260h in FIG. 3. The first normal bitline sense amplifiers NBLSA11 and NBLSA12 and the first ECC bitline sense amplifiers EBLSA11 and EBLSA12 may be included in the bitline sense amplifiers BLSA in FIG. 2, and may be included in the sense amplifier unit in FIG. 3. The first sub-wordline drivers SWD11 and SWD12 may be included in the sub-wordline drivers SWD in FIG. 2, may be disposed between the row decoder 260 and the memory cell array 300 in FIG. 3, and may be used to drive the wordlines WL in FIG. 3. The first bank column decoders BCDEC11 and BCDEC12 may be included in the column decoder CDEC in FIG. 2, and each of the first bank column decoders BCDEC11 and BCDEC12 may correspond to one of the bank column decoders 270a to 270h in FIG. 3. The first intermediate circuit INTMID11 may correspond to at least a portion of a front end of the bank row decoders 260a to 260h in FIG. 3.

In the second semiconductor layer L2b, arrangements of the first bank row decoder BRDEC11, the first normal bitline sense amplifiers NBLSA11 and NBLSA12, the first ECC bitline sense amplifiers EBLSA11 and EBLSA12, the first sub-wordline drivers SWD11 and SWD12, the first bank column decoders BCDEC11 and BCDEC12 and the first intermediate circuit INTMID11 may be similar to those described with reference to FIG. 5.

For example, the first bank row decoder BRDEC11 may be disposed in a second region R2b in the second semiconductor layer L2b that overlaps the first region R1b in the first semiconductor layer L1b in the third direction D3. The first ECC bitline sense amplifiers EBLSA11 and EBLSA12 may be disposed in the second region R2b in the second semiconductor layer L2b. The first normal bitline sense amplifiers NBLSA11 and the first sub-wordline drivers SWD11 may be disposed in a region R31b in the second semiconductor layer L2b that overlaps the first sub-region R_BA11a in the first semiconductor layer L1b in the third direction D3. The first normal bitline sense amplifiers NBLSA12 and the first sub-wordline drivers SWD12 may be disposed in a region R32b in the second semiconductor layer L2b that overlaps the second sub-region R_BA12b in the first semiconductor layer L1b in the third direction D3. The first bank column decoders BCDEC11 and BCDEC12 may be disposed in first bank column decoder regions R41b and R42b, respectively, in the second semiconductor layer L2b. The first intermediate circuit INTMID11 may be disposed in a region R43b in the second semiconductor layer L2b.

Conventionally, the ECC memory cells EMC11 and EMC12 were disposed in one bank array BA1b in the first semiconductor layer L1b, a first bank row decoder was disposed so as not to overlap the bank array region R_BA1b in the second semiconductor layer L2b. In the memory device 10b according to example embodiments, a position of the first bank row decoder BRDEC11 may be moved to the second region R2b overlapping the first region R1b where the ECC memory cells EMC11 and EMC12 are disposed. In addition, to obtain a space for arranging the first bank row decoder BRDEC11, arrangements of other components (e.g., arrangements of the bitline sense amplifiers NBLSA11, NBLSA12, EBLSA11 and EBLSA12 and/or the sub-wordline drivers SWD11 and SWD12) may be partially changed. Accordingly, a size of the memory device 10b may be reduced.

FIG. 11 is a schematic diagram for describing a memory device of FIG. 10, according to one or more embodiments.

Referring to FIG. 11, an example where the first bank row decoder BRDEC11 drives the first bank array BA1b is illustrated.

The first bank array BA1b may include first normal memory cells NMC11L, NMC11R, NMC12L and NCM12R. The first bank row decoder BRDEC11 may be connected only to first parts NMC11R and NMC12L of the first normal memory cells NMC11L, NMC11R, NMC12L and NCM12R, and may drive only the first parts NMC11R and NMC12L of the first normal memory cells NMC11L, NMC11R, NMC12L and NCM12R. For example, the first ECC memory cells EMC11 and EMC12 in the first region R1b in FIG. 10 may be ECC memory cells corresponding to the first parts NMC11R, NMC12L of the first normal memory cells NMC11L, NMC11R, NMC12L and NCM12R.

In some example embodiments, connections between the sub-wordline drivers SWD11 and SWD12 and the memory cells NMC11, NMC12, EMC11 and EMC12 in FIG. 10 may be substantially the same as those described with reference to FIG. 7B. In some example embodiments, connections between the bitline sense amplifiers NBLSA11, NBLSA12, EBLSA11 and EBLSA12 and the memory cells NMC11, NMC12, EMC11 EMC12 in FIG. 10, and connections between the bitline sense amplifiers NBLSA11, NBLSA12, EBLSA11 and EBLSA12 and lines in FIG. 10 may be substantially the same as those described with reference to FIGS. 8B and 8C. In some example embodiments, there may be no empty space in the first region R1b in the first bank array region R_BA1b in FIG. 10, and thus the configuration in which the lines connected to the first bank row decoder BRDEC11 are arranged in the first region R1b described with reference to FIG. 9 may be omitted in the memory device 10b of FIG. 10.

FIGS. 12A and 12B are schematic perspective views of a memory device according to example embodiments. The descriptions repeated with or overlapping with descriptions of FIG. 1 will be omitted in the interest of brevity.

Referring to FIG. 12A, a memory device 12 includes a first semiconductor layer L1, a second semiconductor layer L2 and a third semiconductor layer L3. An example of FIG. 12A may be substantially the same as the example of FIG. 1, except that the memory device 12 further includes the third semiconductor layer L3.

The first semiconductor layer L1, the second semiconductor layer L2 and the third semiconductor layer L3 are disposed or stacked in the third direction D3. Although FIG. 12A illustrates an example where the first semiconductor layer L1 and the third semiconductor layer L3 are disposed on and below the second semiconductor layer L2, respectively, example embodiments are not limited thereto. For example, both the first and third semiconductor layers L1 and L3 may be disposed on or below the second semiconductor layer L2. It is to be understood that although ordinal terms, such as “first,” “second,” “third,” etc., may be used herein to describe various elements, these elements should not be limited by such terms. These terms are used merely to distinguish one element from another and are not used to convey any particular order of the respective elements. For example, a first element could be termed a second element and similarly, a second element could be termed a first element, without departing from the scope of the present disclosure.

As with the first semiconductor layer L1, the third semiconductor layer L3 may include a memory cell array MCA, and may be referred to as a memory cell region or a cell wafer. For example, the memory cell array MCA included in the first semiconductor layer L1 may be referred to as a first memory cell array, and the memory cell array MCA included in the third semiconductor layer L3 may be referred to as a second memory cell array.

Each of the memory cell arrays MCA of the first and third semiconductor layers L1 and L3 may include the plurality of normal memory cells NMC and the plurality of ECC memory cells EMC, respectively. The plurality of ECC memory cells EMC in the first and third semiconductor layers L1 and L3 and the row decoder RDEC in the second semiconductor layer L2 may be arranged to partially and/or completely overlap in a plan view or on a plane.

Referring to FIG. 12B, a memory device 14 includes a first semiconductor layer L1, a second semiconductor layer L2 and a fourth semiconductor layer L4. An example of FIG. 12B may be substantially the same as the example of FIG. 1, except that the memory device 14 further includes the fourth semiconductor layer L4.

The first semiconductor layer L1, the second semiconductor layer L2 and the fourth semiconductor layer L4 are disposed or stacked in the third direction D3. Although FIG. 12B illustrates an example where the fourth semiconductor layer L4 and the second semiconductor layer L2 are disposed on and below the first semiconductor layer L1, respectively, example embodiments are not limited thereto. For example, both the second and fourth semiconductor layers L2 and L4 may be disposed on or below the first semiconductor layer L1.

As with the second semiconductor layer L2, the fourth semiconductor layer L4 may include a peripheral circuit PCKT, and may be referred to as a peripheral circuit region or a peripheral wafer. For example, the peripheral circuit PCKT included in the second semiconductor layer L2 may be referred to as a first peripheral circuit, and the peripheral circuit PCKT included in the fourth semiconductor layer L4 may be referred to as a second peripheral circuit.

The peripheral circuits PCKT of the second and fourth semiconductor layers L2 and L4 may include the row decoder RDEC, respectively. The plurality of ECC memory cells EMC in the first semiconductor layer L1 and the row decoders RDEC in the second and fourth semiconductor layers L2 and L4 may be arranged to partially and/or completely overlap in a plan view or on a plane.

Although not illustrated in detail, a memory device according to example embodiments may include four or more semiconductor layers that are stacked.

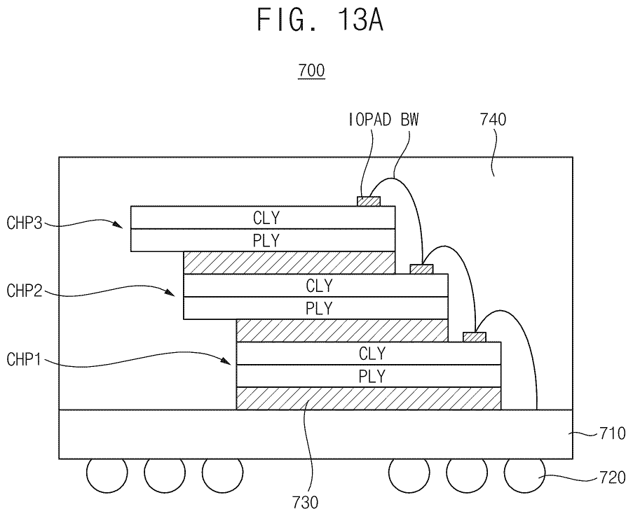

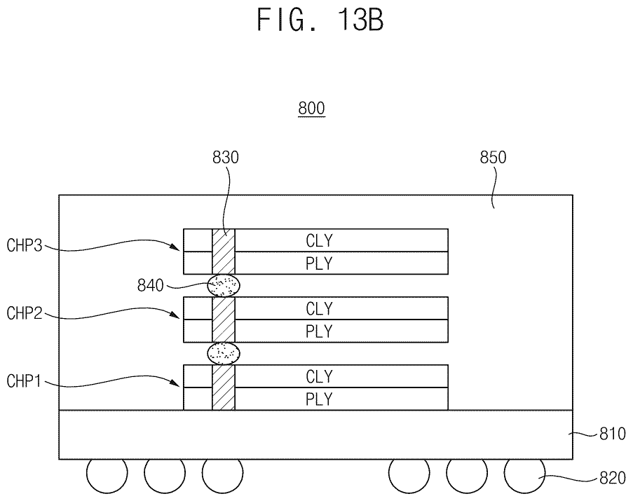

FIGS. 13A and 13B are schematic cross-sectional views of a memory package according to example embodiments.

Referring to FIG. 13A, a memory package 700 includes a base substrate 710 and a plurality of memory chips CHP1, CHP2 and CHP3 vertically stacked on the base substrate 710.

Each of the memory chips CHP1 to CHP3 may include a memory cell layer CLY and a peripheral circuit layer PLY, and may further include a plurality of I/O pads IOPAD. The memory cell layer CLY and the peripheral circuit layer PLY may correspond to the first semiconductor layer L1 and the second semiconductor layer L2 described with reference to FIG. 1, respectively, and further may include said elements described herein to be included in the first semiconductor layer L1 and the second semiconductor layer L2, respectively, according to any of the example embodiments described herein. Each of the memory chips CHP1 to CHP3 may include the memory device according to example embodiments, and may be implemented such that the ECC memory cells EMC and the row decoder RDEC included in different semiconductor layers L1 and L2 are arranged to partially and/or completely overlap in a plan view or on a plane.

In some example embodiments, the memory chips CHP1 to CHP3 may be stacked on the base substrate 710 such that a surface on which the plurality of I/O pads IOPAD are formed faces upwards. In some example embodiments, with respect to each of the memory chips CHP1 to CHP3, the plurality of I/O pads IOPAD may be arranged near one side of the semiconductor substrate. As such, the memory chips CHP1 to CHP3 may be stacked scalariformly, that is, in a step shape, such that the plurality of I/O pads IOPAD of each memory chip may be exposed. In such stacked state, the memory chips CHP1 to CHP3 may be electrically connected to the base substrate 710 through a plurality of bonding wires BW.

The stacked memory chips CHP1 to CHP3 and the plurality of bonding wires BW may be fixed by a sealing member (e.g., encapsulant) 740, and adhesive members 730 may be disposed between the base substrate 710 and each of the adjacent memory chips CHP1 to CHP3. Conductive bumps 720 may be formed on a bottom surface of the base substrate 710 for providing electrical connections to an external device.

Referring to FIG. 13B, a memory package 800 includes a base substrate 810 and the plurality of memory chips CHP1 to CHP3 stacked on the base substrate 810. The descriptions repeated with or overlapping with descriptions of FIG. 13A will be omitted in the interest of brevity.

Each of the memory chips CHP1 to CHP3 may include the memory cell layer CLY and the peripheral circuit layer PLY vertically stacked, and may further include a plurality of through silicon vias (TSVs) 830.

In some example embodiments, with respect to each of the memory chips CHP1 to CHP3, the plurality of TSVs 830 may be arranged at the same locations in each memory chip. As such, the memory chips CHP1 to CHP3 may be vertically stacked (i.e., in the third direction D3) such that the plurality of TSVs 830 of each memory chip may be completely overlapped (e.g., arrangements of the plurality of TSVs 830 may be perfectly matched (i.e., vertically aligned) in the memory chips CHP1 to CHP3). In such stacked state, the memory chips CHP1 to CHP3 may be electrically connected to one another and the base substrate 810 through the plurality of TSVs 830 and conductive material 840 between vertically adjacent TSVs 830.

Conductive bumps 820 and a sealing member 850 may be substantially the same as the conductive bumps 720 and the sealing member 740, respectively, in FIG. 13A.

FIG. 14 is a block diagram illustrating a memory system according to example embodiments.

Referring to FIG. 14, a memory system 1000 includes a memory controller 1200 and a memory device 1400. The memory system 1000 may further include a plurality of signal lines 1300 that electrically connect the memory controller 1200 with the memory device 1400.

The memory device 1400 may be controlled by the memory controller 1200. For example, based on requests from a host (not illustrated), the memory controller 1200 may store (e.g., write or program) data into the memory device 1400, or may retrieve (e.g., read or sense) data from the memory device 1400. The memory device 1400 may be the memory device according to example embodiments, and may be implemented such that the ECC memory cells EMC and the row decoder RDEC included in different semiconductor layers L1 and L2 are arranged to partially and/or completely overlap in a plan view or on a plane.

The plurality of signal lines 1300 may include control lines, command lines, address lines, data input/output (I/O) lines and power lines. The memory controller 1200 may transmit a command CMD, an address ADDR and a control signal CTRL to the memory device 1400 via the command lines, the address lines and the control lines, may exchange a data signal DS with the memory device 1400 via the data I/O lines, and may transmit a power supply voltage PWR to the memory device 1400 via the power lines. Although not illustrated in detail, the plurality of signal lines 1300 may further include data strobe signal (DQS) lines for transmitting a DQS signal.

The example embodiments may be applied to various electronic devices and systems that include the memory devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A memory device, comprising:
a first semiconductor layer including:
a memory cell array connected to a plurality of wordlines and a plurality of bitlines, the memory cell array including a plurality of normal memory cells configured to store normal data and a plurality of error correction code (ECC) memory cells configured to store ECC data, the plurality of wordlines extending in a first direction, the plurality of bitlines extending in a second direction intersecting the first direction; and
a second semiconductor layer on the first semiconductor layer in a third direction perpendicular to the first direction and the second direction, the second semiconductor layer including:
a peripheral circuit configured to control the memory cell array, the peripheral circuit including a row decoder, and
wherein at least a portion of a region including the plurality of ECC memory cells in the first semiconductor layer and at least a portion of a region including the row decoder in the second semiconductor layer at least partially overlap in a plan view.

2. The memory device of claim 1,
wherein the plurality of normal memory cells include first normal memory cells and second normal memory cells,
wherein the plurality of ECC memory cells include first ECC memory cells and second ECC memory cells corresponding to the first normal memory cells and the second normal memory cells, respectively,
wherein the memory cell array further includes:
a first bank array and a second bank array spaced apart from one another, the first and second bank arrays including the first normal memory cells and the second normal memory cells, respectively,
wherein the row decoder includes:
a first bank row decoder configured to drive the first and second normal memory cells and the first and second ECC memory cells,
wherein the first and second ECC memory cells are in a first region between the first and second bank arrays in the first semiconductor layer, and
wherein the first bank row decoder is in a second region in the second semiconductor layer that at least partially overlaps the first region in the first semiconductor layer in a plan view.

3. The memory device of claim 2,
wherein the peripheral circuit further includes:
first sub-wordline drivers configured to drive the first normal memory cells and the first ECC memory cells, and
wherein the first sub-wordline drivers are in a third region in the second semiconductor layer that at least partially overlaps a first bank array region including the first bank array in the first semiconductor layer in the plan view.

4. The memory device of claim 3,
wherein the first normal memory cells and first parts of the first sub-wordline drivers are electrically connected to each other through first vertical lines extending in the third direction and first wordlines among the plurality of wordlines,
wherein the first ECC memory cells and second parts of the first sub-wordline drivers are electrically connected to each other through second vertical lines extending in the third direction and second wordlines among the plurality of wordlines, and
wherein, with respect to the first and second vertical lines, a direction in which the first wordlines extend and a direction in which the second wordlines extend are opposite to each other.

5. The memory device of claim 3,
wherein the peripheral circuit further includes:
first normal bitline sense amplifiers configured to drive the first normal memory cells, and
wherein the first normal bitline sense amplifiers are in the third region in the second semiconductor layer.

6. The memory device of claim 2,
wherein the peripheral circuit further includes:
first ECC bitline sense amplifiers configured to drive the first ECC memory cells, and
wherein the first ECC bitline sense amplifiers are in the second region in the second semiconductor layer.

7. The memory device of claim 6,
wherein the peripheral circuit further includes:
a first bank column decoder in a first bank column decoder region in the second semiconductor layer and configured to drive the first normal memory cells and the first ECC memory cells, and
wherein at least one line connected to the first ECC bitline sense amplifiers is in a third region in the second semiconductor layer that is adjacent to the second region in the second semiconductor layer and the first bank column decoder region.

8. The memory device of claim 6, wherein the first ECC bitline sense amplifiers are adjacent to at least one edge of the second region in the second semiconductor layer.

9. The memory device of claim 2,
wherein the first ECC memory cells are in a first ECC cell region in the first region in the first semiconductor layer,
wherein the second ECC memory cells are in a second ECC cell region in the first region in the first semiconductor layer, and
wherein the first ECC cell region is adjacent to the first bank array, and the second ECC cell region is adjacent to the second bank array.

10. The memory device of claim 9, wherein at least one line electrically connected to the first bank row decoder is in a region other than the first and second ECC cell regions in the first region in the first semiconductor layer.

11. The memory device of claim 10, wherein the at least one line electrically connected to the first bank row decoder is between the first and second ECC cell regions in the first region in the first semiconductor layer.

12. The memory device of claim 2, wherein the first bank row decoder is configured to drive parts of the first and second normal memory cells.

13. The memory device of claim 12, wherein the first bank row decoder is configured to drive only the parts of the first and second normal memory cells that are adjacent to the first region in the first semiconductor layer.

14. The memory device of claim 1,
wherein the plurality of normal memory cells include first normal memory cells,
wherein the plurality of ECC memory cells include first ECC memory cells corresponding to the first normal memory cells,
wherein the memory cell array further includes:
a first bank array in a first bank array region in the first semiconductor layer, the first bank array including the first normal memory cells,
wherein the row decoder includes:
a first bank row decoder configured to drive the first normal memory cells and the first ECC memory cells,
wherein the first ECC memory cells are in a first region included in the first bank array region in the first semiconductor layer, and
wherein the first bank row decoder is in a second region in the second semiconductor layer that at least partially overlaps the first region in the first semiconductor layer in a plan view.

15. The memory device of claim 14, wherein the first region in the first semiconductor layer is at a center of the first bank array region.

16. The memory device of claim 14, wherein the first bank row decoder is configured to drive parts of the first normal memory cells.

17. The memory device of claim 16, wherein the first bank row decoder is configured to drive only the parts of the first normal memory cells that are adjacent to the first region in the first semiconductor layer.

18. The memory device of claim 1,
wherein the first semiconductor layer further includes a first bonding pad,
wherein the second semiconductor layer further includes a second bonding pad electrically connected to the first bonding pad, and
wherein the first and second semiconductor layers are electrically connected in the third direction by the first and second bonding pads.

19. A memory package, comprising:
a base substrate; and
a plurality of memory chips on the base substrate,
wherein each of the plurality of memory chips includes:
a first semiconductor layer including:
a memory cell array connected to a plurality of wordlines and a plurality of bitlines, the memory cell array including a plurality of normal memory cells configured to store normal data and a plurality of error correction code (ECC) memory cells configured to store ECC data, the plurality of wordlines extending in a first direction, the plurality of bitlines extending in a second direction intersecting the first direction; and
a second semiconductor layer on the first semiconductor layer in a third direction perpendicular to both the first direction and the second direction, the second semiconductor layer including:
a peripheral circuit configured to control the memory cell array, the peripheral circuit including a row decoder, and
wherein at least a portion of a region including the plurality of ECC memory cells in the first semiconductor layer and at least a portion of a region including the row decoder in the second semiconductor layer at least partially overlap in a plan view.

20. A memory device, comprising:
a first semiconductor layer including:
a memory cell array connected to a plurality of wordlines and a plurality of bitlines, the plurality of wordlines extending in a first direction, the plurality of bitlines extending in a second direction intersecting the first direction; and
a first bonding pad; and
a second semiconductor layer on the first semiconductor layer in a third direction perpendicular to the first direction and the second direction, the second semiconductor layer including:
a peripheral circuit configured to control the memory cell array; and
a second bonding pad connected to the first bonding pad,
wherein the memory cell array includes:
a plurality of normal memory cells configured to store normal data, the plurality of normal memory cells including first normal memory cells and second normal memory cells that are spaced apart from each other; and
a plurality of error correction code (ECC) memory cells configured to store ECC data, the plurality of ECC memory cells including first ECC memory cells and second ECC memory cells that correspond to the first normal memory cells and the second normal memory cells, respectively,
wherein the peripheral circuit includes:
a first row decoder configured to drive the first and second normal memory cells and the first and second ECC memory cells;
first and second normal bitline sense amplifiers configured to drive the first and second normal memory cells, respectively;
first and second ECC bitline sense amplifiers configured to drive the first and second ECC memory cells, respectively;
first sub-wordline drivers configured to drive the first normal memory cells and the first ECC memory cells; and
second sub-wordline drivers configured to drive the second normal memory cells and the second ECC memory cells,
wherein the first and second ECC memory cells are in a first region between the first and second normal memory cells in the first semiconductor layer,
wherein the first row decoder and the first and second ECC bitline sense amplifiers are in a second region in the second semiconductor layer that at least partially overlaps the first region in the first semiconductor layer in a plan view, and
wherein the first and second normal bitline sense amplifiers and the first and second sub-wordline drivers are in a third region in the second semiconductor layer that is adjacent to the second region in the second semiconductor layer.
